(19) United States
(12) Patent Application Publication
(10) Pub. No.: US 2026/0102664 A1
(43) Pub. Date: Apr. 16, 2026

(54) Golf Metal Wood Club with a Backward Shifted Head and Method for Making a Backward Shifted Metal Wood Golf Club Head

(71) Applicant: Joshua Lin, Shanghai (CN)

(72) Inventor: Joshua Lin, Shanghai (CN)

(21) Appl. No.: 18/911,326

(22) Filed: Oct. 10, 2024

(51) Int. Cl. A63B 53/04; G06F 30/17

(52) U.S. Cl. CPC A63B 53/0466; G06F 30/17

(57) ABSTRACT

A golf metal wood club has a shaft and a head firmly connected to a distal end of the shaft and located backward shifted relative to an extension line of the shaft so that the golfer is able to have a consistent swing regardless what type of golf club is used. The club face of the head has a loft and larger the loft is, the smaller the backward shifted amount is within a loft range of 1<loft<=70.

### TECHNICAL FIELD

The present invention relates to the technical field of a golf club, and more particularly to a golf metal wood club with a backward shifted club face.

### BACKGROUND

Golfing is now a great past-time for almost all walks of life as the cost is becoming more and more affordable unlike thirty or forty years ago, in which golfing is almost monopolized by the rich. As its inexpensive cost and easy for the players to enjoy the fun of the game, more and more people are willing to take courses or trying to learn the skills required and then master the game. For most beginners and even some semi-pro players, when trying to use the driver to hit the golf ball, slice and hook are two most common trajectories. Of course, this kind of mistakes can be contributed to lack of practice or some environmental factors. However, put aside all human errors and environmental distractions, there is one still important effect that affects the golf ball trajectory deeply, that is, the club face design of a golf club. Around seventies (70s), a company called “Ping” first introduces a concept of reallocating the club head to cope with the challenges most golfers would have to deal with and overcome, particularly, slice. This design is brought to the world and targeted to iron club in particular. Reallocating the club head is to move the club head, especially, the club face of the club head, to the hind edge in relation to the shaft of the club when looking down from the position of striking a ball, for which the purpose of the design is mainly on reducing the chances of having slices when a golfer is using the iron club to make contact with the golf ball. Using this reallocated club head, the golfer would have a lot more margin for fault tolerance and a lot more swing movement consistence. Particularly, a golfer using this reallocated designed club head would benefit from the following advantages.

Improved precision: The reallocated designed club head can help the golfer align the club face of the club head with the ball so that when the club face makes contact with the golf ball, the club face is able to directly face the ball, which is most beneficial to the beginners to maintain consistent swing movement.

Higher trajectory: The center of gravity of the reallocated club face of the club head is lower than that of the club head with no backward shifted club face, which helps the golfer strike the ball high. This advantage is especially good for the beginners with slow swing movement to achieve the purpose of further distance and better control.

Enhanced fault tolerance: With a reallocated club face, the golfer will be able to square up the face easier. Along with other reallocated irons that golfers use, it boosts consistency and allows for more consistent ball striking performance. This design helps a great deal to the beginners and those who have not developed a consistent swing movement.

Increased control: To golfers who are used to strike the ball with the heel of the club face, the reallocated club face of the golf ball helps correct the faulty swing movement and thus improve the effective swing as well as the control of the ball trajectory.

Taking all the reasons above into consideration, it is common to see that almost all iron clubs today have this reallocated club face design, as it provides the golfers with more consistent swing movement and obviates the situations where the golfers have to adjust their swing movement habit to different club designs. During a round of golf, golfers often will have to deal with different terrains with different clubs including drivers, irons and putters. As all irons on the market are equipped with a reallocated club face, it is inconsistent with all hybrids or metal woods on the market. Due to the difference in reallocated club face relative to the hosel, it will be impossible for golfers to square up the club face when using the same swing. Furthermore, golf performance is highly related to golfers swing movement so that if the golfer constantly changes his/her swing movement to deal with different club face designs, the final score might not be good and might be even worse than the situation where the golfer uses only one type of golf clubs. To make the situation worse is that some golf club even has a club face design that is moved to the front of the shaft, which complicates the game into another level. As a result of this dilemma, it is beneficial to have a universal club face design to allow the golfer to strike the golf ball with a muscle memory, that is, a swing movement without any alteration to adapt to different types of club (Woods, Hybrids, Irons, Wedges).

### SUMMARY OF THE INVENTION

In one aspect of the present application, the objective of this application is to provide a golf metal wood club having a shaft, a head and a neck firmly connecting the head to the shaft, wherein the head having a club face which is backward shifted relative to an extension line of the shaft.

Another objective of this application is that a value of the backward shifted club face is determined based on loft of the club face.

Another objective of this application is that the club face has a loft and larger the loft is, the smaller the backward shift is within a loft range of 1<loft<=70.

Another objective of this application is to provide a method of making a golf metal wood club having a shaft and a head provided with a club face, the method comprising the steps of:
creating a database based on lofts of all backward shifted club faces of iron clubs; dividing the database into loft ranges according to loft difference;
finding backward shift mean in each of the loft ranges;
creating a backward shift prediction table based on the mean of the loft ranges; and determining backward shift value of a wood club to be made according to the prediction table.

Another objective of this application is that the loft difference between loft ranges has at least 25% overlapping.

Another objective of this application is that loft difference in each of the loft ranges is no more than 4 degrees.

Another objective of this application is that the method further comprises a step of providing modification room after the backward shift mean finding step.

Another objective of this application is that the step of providing modification room is to provide a room for adjustment to the backward shift mean so found.

Another objective of this application is that STDEVP is adopted for the modification room providing step.

Another objective of this application is that in the mean finding step, element number (>1 and <4) is used to find midpoint between the element.

Another objective of this application is that loft difference in each of the loft ranges is 0, 1, 2, 3 or 4.

### BRIEF DESCRIPTION OF THE DRAWINGS

FIG. 1 is a schematic plan view of the metal wood club head designed in accordance with the present invention;

FIG. 2a is a schematic view of a metal wood club head of the present invention, and FIGS. 2b and 2c are schematic views of two iron club heads of the present invention with different lofts;

FIGS. 3a, 3b and 3c are schematic views showing the comparison between golf ball trajectories respectively created by traditional golf club and golf club with backward-shifted club face design;

FIGS. 4a and 4b are also schematic views showing the comparison between golf ball trajectories respectively and simultaneously created by a metal wood golf club constructed in accordance with the present invention and a traditional wood golf club; and

FIGS. 5a, 5b are schematic views showing points of contact of the golf ball by different golf clubs.

FIG. 6 is a chart showing correlation between loft ranges and backward shifted averages.

FIG. 7 is a chart showing correlation between backward shift averages and population standard deviation in loft ranges 8-20.

### DETAILED DESCRIPTION

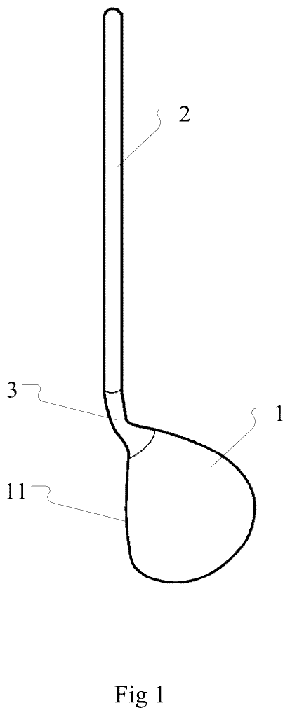

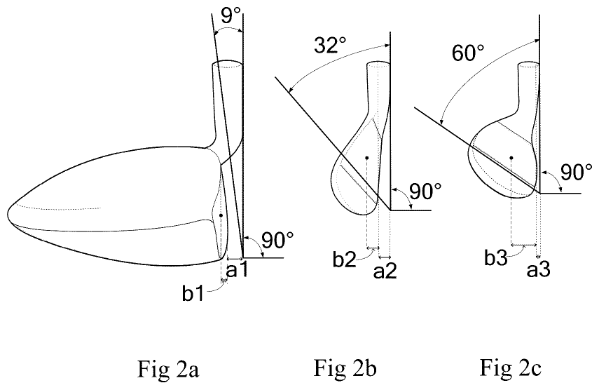

In order to solve the problem of not being able to hit a golf ball in a single swing movement at the same point of contact with the ball, the preferred embodiment of the present invention presented a new golf metal wood club head design, where the club head is backward shifted relative to the extension line of the golf club shaft. In view of FIG. 1, the golf club constructed in accordance with the present invention has a head 1, a shaft 2 with a hosel and a neck 3 firmly connecting the head 1 to the shaft 2. The head 1 has a club face 11 situated behind an extension line of the shaft 2. That is, the club face 11 of the head 1 is backward shifted in relation to the extension line of the shaft 2 and the backward shifted amount is determined by a loft (slanted angle) of the club face 11, which also shares the same point of contact of the golf ball with the existing iron club and wedge cub, both bear the same club face backward-shifted design. The backward shift of the club face stands for the backward shifted distance of the front edge of the club face from the extension line of the golf shaft. A loft is the slanted angle of the club face in relation to the golf shaft 2. For example, as shown in FIG. 2a, the loft of this one metal wood is 9 degrees and the backward shifted distance is a1.

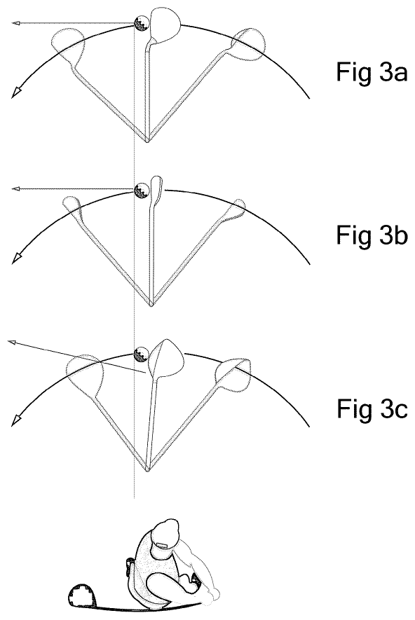

Point of contact consistency analysis: This analysis includes the moment the club face strikes the golf ball and the impact point when the club face contacts the ball. The moment the club face strikes the ball is the timing when the club face makes contact with the ball. As shown in FIGS. 3a, 3b and 3c, the curved line represents the golfer's swing movement, and the straight line represents the intended direction to which the golfer wish the ball can travel along this direction. The club face 11 is relatively open to the straight line and the club face 11 is relatively closed to the straight line. The switch moment between the relative open and relative close of the club face 11 to the straight line is called “contact timing”. From the showing of FIGS. 3a, 3b and 3c, it is noted that at the same contact timing, the golf clubs with the backward shifted club face 11, i.e., FIG. 3a metal wood club and FIG. 3b iron club, would allow the ball to travel along the intended straight line. Instead of traveling along the straight line as it should like FIG. 3a and FIG. 3b, the ball would travel forward and upward in a slanted way in relation to the ground, when the ball is struck by a traditional golf club with no backward shifted club face design, as showing in FIG. 3c. To make things worse is that some golf club even is equipped with a forward shifted club face. The golf ball travels along a direction to which the golfer aims at, which means basically, the golf ball should travel wherever the golfer aims at if the golfer's swing movement is consistent. However if the club face of one club is not consistent to others, the golfer's consistent swing movement would not be able to send the ball to the intended direction.

In that sense, the golfer may send the golf ball in different directions with the same swing movement if the golfer chooses to use a club with backward shifted club face design and a club without backward (or forward) shifted club face design. Under the current situation where there are different types of clubs, in order to ensure the ball to travel along a predetermined direction, the contact timing created by the golfer would certainly not be the same as the club face 1 design of different clubs is not the same, which is not very beneficial to the golfer, especially in a round of golf where every gofer is trying their best to have their best.

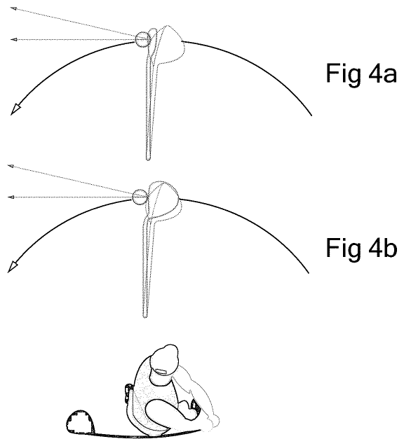

With reference to FIGS. 4a and 4b, where schematic views showing the comparison between two different types of club heads are shown. FIG. 4a respectively indicates trajectory comparison between an iron club head with backward-shifted club face and a traditional wood cub head without club face backward-shifted design. FIG. 4b respectively indicates trajectory comparison between a metal wood club head with backward-shifted club face and a traditional wood club head without club face backward-shifted design

Referring to FIGS. 1 and 2, because the point of contact is highly related to the loft of the club face 11, in order to ensure the point of contact and the contact timing that the golfer strikes the ball remains the same while using different clubs, it is then necessary to learn the relationship between loft of the club face 11 and the backward shifted amount in relation to the extension line of the shaft 2. The lofts in each of the clubs shown in FIGS. 2a, 2b and 2c respectively are 9, 32 and 60 degrees relative to the extension of the shaft 2. The definition of backward shifted amount is based on the distance between the front edge of the neck 3 to the font edge of the club face 11. However, the best point of contact (sweet spot; the black dot in FIGS. 2a, 2b and 2c) is not located at the front edge of the club face 11. It is also noted that due to the existence of this loft, the club face 11 itself is shifted backward, the backward shifted amount such as b1, b2 and b3 in FIGS. 2a, 2b and 2c is thus determined. Hence, it is crucial to incorporate the backward shifted amount of the club face 11 while determining the total backward shifted amount to maintain the point of contact at the center of the club face 11. In general, greater the loft is (e.g., FIG. 2b and FIG. 2c), less the backward shifted amount will be (e.g., a2 and a3) and this is because the point of contact is further from the front edge of the club face 11. The club face 11 itself bears more of the backward shifted amount. On the other hand, less the loft (e.g., FIG. 2a) is, greater the backward shifted amount will be (e.g., b1 in FIG. 2a). It is thus concluded that the greater the loft is, the less the backward shifted amount will be; and the less the loft is, the greater the backward shifted amount will be. The aim is that the backward shifted amount in different clubs pluses the backward shifted amount of the club face 11 itself are equal so that at the same contact timing while using different clubs, the golfer will still have the same point of contact. Therefore, to ensure that when a golfer is using these different clubs (FIGS. 2a, 2b and 2c) and still has the same point of contact, a1+b1=a2+b2=a3+b3.

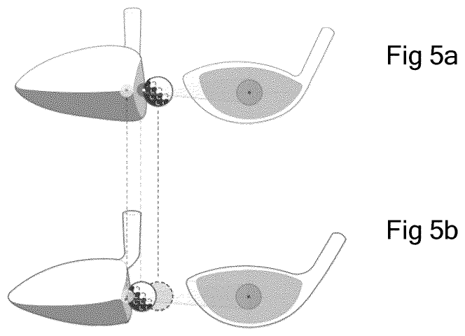

With reference to FIG. 5a, a traditional wood club is shown and not equipped with an backward shifted mechanism such that the contact timing is earlier than those with backward shifted, which results in that the point of contact for this kind of club is not consistent to those with backward shifted mechanism. And of course, the golfer's swing will be seriously affected by this club design. Instead, referring to FIG. 5b, a metal wood (Driver) with loft of 9 degrees and constructed in accordance with the preferred embodiment of the present invention is equipped with an backward shifted mechanism based on the design concept of, for example, the current commercially available 7 iron with loft of 32 degrees and wedge with loft of 60 degrees to have the same contact timing and point of contact.

In real life, golf club driver normally is made of carbon fiber or light-weight titanium alloy, but because only driver can fulfill long distance requirement, the length of driver is much longer than that of the iron and still needs quite a swing to achieve long distance requirement. In conventional days, the technology is not able to meet the requirements of making a metal wood club which is light-weight enough, but still has a neck to complete the backward shifted design. As the technology advances, some carbon fiber and/or titanium alloy is able to be adopted for making such a club.

Because there are different lofts as well as various types of backward shifted design in the existing clubs, such as iron 7 (32 degrees) or wedge (60 degrees), clubs with the same lofts may well have different backward shifted club face and this may easily be found in clubs of different brands. However, we can still see a very definite correlation in the data, which is the less lofted clubs always have more backward shifted within the same model. Using the data, we can easily conclude that there is an inverse ratio relationship between the loft and the backward shifted amount. In order to assess or calculate the appropriate backward shifted amount to be used in the driver of the preferred embodiment of the present invention, the following provides a backward-shifted amount method for a metal wood club.

Building up backward-shifted amount database;

With reference to table 1, this database is created by collecting all the commercially available golf clubs with backward shifted mechanism, including parameters of lofts and backward shifted amount.

Classifying parameters based on lofts to have loft ranges respectively with four-degree difference, in which, less the loft range difference is, the more accurate the backward shifted amount to be built is. Preferably, every two neighboring loft ranges should have at least 25% overlapping angles. In table 1, each loft range difference is 4, however, this difference may be modified according to different requirements, for example, the difference may be 3, 2 or 1.

The more lofted club will have less backward shift, due to the fact that the impact point on the club face with the golf ball will be further away from the leading edge on the horizontal axis. Therefore, the club with less loft, will have more backward shift, because the club face's impact point with the ball will be closer to the leading edge on the horizontal axis. In fact, it is crucial to rely on loft and backward shift to measure the actual impact point of the ball with the club face because the amount of backward shift affects the timing of the impact and loft affects the actual impact point with the club face.

Backward shift merely measures to the leading edge of the club face. And the club face's actual impact with the ball will be closer to the vertical center of the face rather than the leading edge. Based on this observed reality, the more lofted club will see impact with the ball further away from the leading edge in the horizontal axis. On the other hand, the less lofted club will see impact with the ball closer to the leading edge on the horizontal axis.

In conclusion, the goal is to allow golfers to have similar impact position with the ball with all the different clubs in the bag. Below table shows the backward shifted average amount for each loft range. The amount is calculated through polynomial trend calculation and extrapolation after collecting the backward shift of a wide variety of models of irons/wedges that are on the market.

TABLE 1
POLYNOMIAL TREND CALCULATION

| | BACKWARD | |
|---|---|---|
| LOFT RANGE | SHIFTED AVERAGE | STDEVP |
| 8 ≤ Loft ≤ 12 | 6.36 | 1.72 |
| 10 ≤ Loft ≤ 14 | 5.98 | 1.65 |
| 12 ≤ Loft ≤ 16 | 5.60 | 1.57 |
| 14 ≤ Loft ≤ 18 | 5.26 | 1.50 |
| 16 ≤ Loft ≤ 20 | 4.92 | 1.43 |
| 18 ≤ Loft ≤ 22 | 4.74 | 1.40 |
| 20 ≤ Loft ≤ 24 | 4.17 | 1.30 |
| 22 ≤ Loft ≤ 26 | 3.98 | 1.22 |
| 24 ≤ Loft ≤ 28 | 3.77 | 1.22 |
| 26 ≤ Loft ≤ 30 | 3.37 | 1.05 |
| 28 ≤ Loft ≤ 32 | 3.26 | 1.08 |
| 30 ≤ Loft ≤ 34 | 2.95 | 0.99 |
| 32 ≤ Loft ≤ 36 | 2.93 | 1.06 |
| 34 ≤ Loft ≤ 38 | 2.52 | 0.92 |
| 36 ≤ Loft ≤ 40 | 2.50 | 0.92 |
| 38 ≤ Loft ≤ 42 | 2.16 | 0.89 |
| 40 ≤ Loft ≤ 44 | 2.08 | 0.85 |
| 42 ≤ Loft ≤ 46 | 1.90 | 0.80 |
| 44 ≤ Loft ≤ 48 | 1.78 | 0.86 |
| 46 ≤ Loft ≤ 50 | 1.64 | 0.80 |
| 48 ≤ Loft ≤ 52 | 1.78 | 0.80 |
| 50 ≤ Loft ≤ 54 | 1.65 | 0.76 |
| 52 ≤ Loft ≤ 56 | 1.56 | 0.69 |
| 54 ≤ Loft ≤ 58 | 1.5 | 0.69 |
| 56 ≤ Loft ≤ 60 | 1.42 | 0.69 |
| 58 ≤ Loft ≤ 62 | 1.32 | 0.65 |

Methods of dividing the angles into several loft ranges can be numerous and the essence is that the smaller the angle difference is between two adjacent loft ranges, the more accurate the estimated (calculated) backward shifted amount will be. For example, in Table 1, the first loft range is 8 degrees to 12 degrees and the second loft range is between 10 degrees to 14 degrees. The loft difference in the first loft range is 4 degrees, however, the loft difference may be adjustable according to different requirements. Therefore, the loft difference maybe 3, 2, 1 or even 0 and should not go beyond the number of 4. Should the first loft range be between 8 degrees to 11 degrees and the second loft range be between 12 degrees to 14 degrees, the final outcome of the estimated backward shifted amount would be more accurate than the previously presented example, such that Table 1 is only an explanatory example of dividing the angles into different loft ranges and should not be construed as limitation to the scope of the preferred embodiment of the preset invention. Also, the overlapping angles between two adjacent loft ranges rule out the possibility of abnormality in the final result. Following is an introduction of how the backward shifted amount is determined for a metal wood.

First of all, loft and backward shift information of various series of irons/wedges published by TaylorMade, PING, Titleist, Cobra, Callaway (from 18 degrees to 62 degrees since these are clubs with backward shift on the market) are collected as a database.

With all the existing data points, it is then able to calculate the backward shift average for each loft range from 18-62 degrees. Then in order to find out the backward shifted amount for drivers/metal wood (from 8 to 18 degrees), it needs to first decide the degree of the polynomial based on the complexity of the current data sets. Then it is necessary to extrapolate to find out the backward shift averages for clubs from 8-18 degrees (for which is what metal wood is using to decide the amount of backward shift needed). In this case, a quadratic polynomial (degree 2) was chosen to balance complexity and overfitting; hence, the following steps:

$$Y = A {x}^{2} + B x + C$$

where Y is the backward shifted average
X is the loft range
A, B, C are the coefficients determined by fitting the polynomial to the data.
1. Fit the Polynomial: Use a method like least squares fitting to determine the coefficients of the polynomial that best fit the data.
2. Evaluate the Fit: Check the goodness of fit using metrics like R squared, to ensure the polynomial captures the underlying trend well. In this case, R-squared=0.9976.

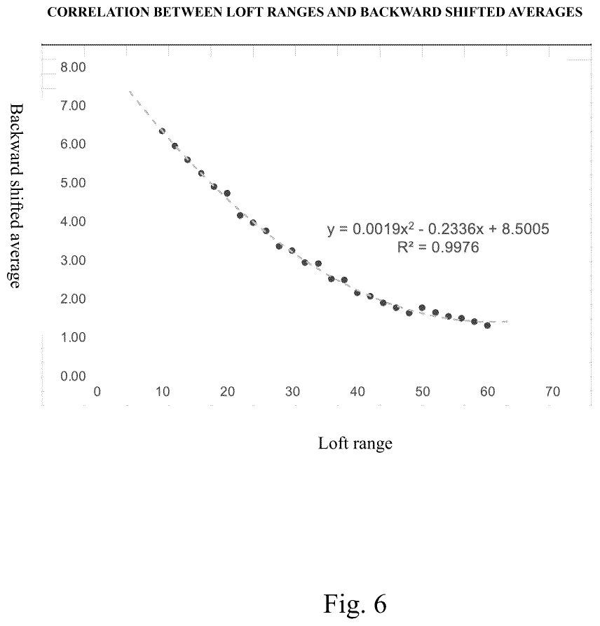

Here first plot the data points so calculated from raw data (which are clubs from 18-62 degrees), shown in blue dots in FIG. 6.

Where the blue dots represent the calculation result using the equation and red dots represent the predicted backward shifted average when there is no such loft in the market. By extrapolating the line of best fit, we have the quadratic formula:

$$Y = 0.0019 {X}^{2} - 0.2336 X + 8.5005$$

It can then calculate the backward shifted average for: 8≤Loft≤12, 10≤Loft≤14, 12≤Loft≤16, 14≤Loft≤18, 16≤Loft≤20, shown in red dots in FIG. 6. When plugging in the line of best fit, the loft used is the mid point of each loft range, hence X=10, 12, 14, 16, and 18, respectively, namely element number (>1 and <4) is used to find midpoint between the elements.

As mentioned, with the existing data points we collect from Top 5 brands on the loft and backward shifted information, it is able to calculate the backward shifted average for each loft range from 18-62 degrees. Then it is able to find out the standard deviation of the backward shifted average for each loft range (18-62 degrees), by using the standard deviation formula.

$$σ = \sqrt{\frac{\sum {( {x}_{i} - μ )}^{2}}{N}} \qquad Formula$$

$$\begin{matrix}σ = population standard deviation \\ N = the size of the population \\ {x}_{i} = each value from the population \\ μ = the population mean\end{matrix}$$

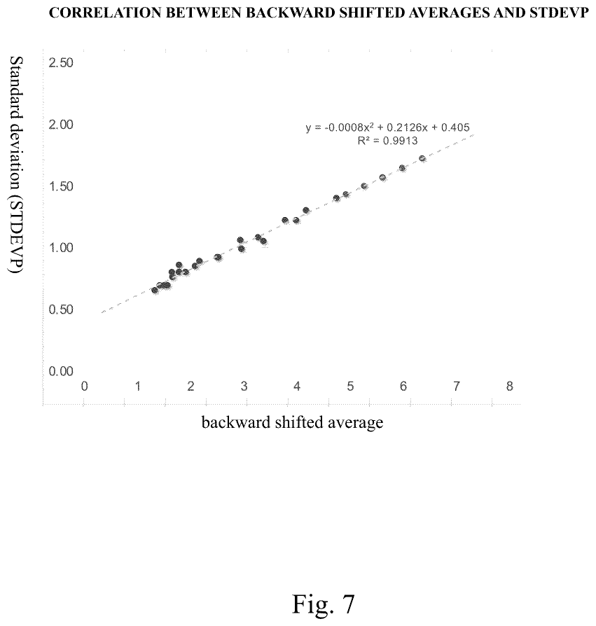

Now with backward shifted average and respective standard deviation for loft range 18-62 degrees, it is able to extrapolate to find out the standard deviation for loft range 8-18 degrees. The degree of the polynomial used between backward shifted average and standard deviation is also quadratic (raw data points shown in blue dots along with the line of best fit in FIG. 7). We can thus extrapolate to find out the STDEVP value for clubs with 8≤Loft<12, 10≤Loft≤14, 12≤Loft≤16, 14≤Loft≤18, and 16≤Loft≤20, shown in red dots in FIG. 7. Here, the quadratic polynomial seems to be the most fit. (R-squared=0.9913)

$$Y = - 0.0008 {X}^{2} + 0.2126 X + 0.405$$

where:
Y is the STDEVP
X is the backward shifted average.
A, B and C are the coefficients determined by fitting the polynomial to the data.

Fitting Process: The numpy.polyfit function was used to fit the polynomial to the data, which minimizes the sum of the squared differences between the observed values and the values predicted by the polynomial.

Extrapolation: Once the polynomial is fitted, it can be used to extrapolate (predict) values for loft ranges not in the original database, ensuring that the predictions follow the observed trend in the market. It is also noted the table and the formula above also indicate that when loft increases, the amount of backward shift should decrease. For the driver of the preferred embodiment of the present invention, this will also be the trend to be followed since the goal is to make sure the clubs so made are consistent with the backward shifted set for all the other irons/wedges in the market. It also needs to emphasize that, CG (center of gravity) of a club is not relevant to what was discussed. The metal woods only affect the timing of the closure for the club face, which helps match up with all the various clubs (except for putter) in the bag.

The following shows an example of how the backward shifted average amount and STDEVP for degrees 8-18 is obtained from extrapolation.

Backward shifted average for 12 [symbol] Loft [symbol] 16,

$$X = 14 ;$$

$$\begin{matrix}Y = 0. 19 {X}^{2} - 0.2336 X + 8.5005 \\ = 0.0019 * {( 14 )}^{2} - 0 \text{.2336} * ( 14 ) + 8.5005 \\ = 0.37 24 - 3.2704 + 8.5005 \\ = 5.6 25\end{matrix}$$

Hence, the backward shifted average for 12 [symbol] Loft [symbol] 16 is around 5.60 mm.

STDEVP for 12 [symbol] Loft [symbol] 16, backward shifted average is around 5.60 mm,

$$X = 5.6 ;$$

$$\begin{matrix}Y = - 0.0008 {X}^{2} + 0.2126 X + 0.405 \\ = - 0.0008 * {( 5.60 )}^{2} + 0 \text{.2126} * ( 5.60 ) + 0.405 \\ = - 0.025088 + 1.19056 + 0.405 \\ = 1.570472\end{matrix}$$

Hence, the STDEVP for 12 [symbol] Loft [symbol] 16 is around 1.57.

Therefore, when we need to design metal wood clubs of the preferred embodiment of the present invention, we know, for instance, the amount of backward shifted needed for loft 12-16 degrees, should be 5.60 mm±1.57. (as shown in Table 1).

It is also noted that the club face has a loft and larger the loft is, the smaller the backward shift is within a loft range of 1<loft<=70.

The present invention is described above in detail with reference to the embodiments of the accompanying drawings, and a person of ordinary skill in the art may make various modifications to the present invention according to the above description. Therefore, some details in the embodiments shall not constitute a limitation on the present invention, and the protection scope of the present invention shall be subject to the scope of the appended claims.

1. In a golf metal wood club having a shaft with a hosel, a head and a neck firmly connecting the head to the shaft, wherein the improvement comprises:
the head having a club face which is backward shifted relative to a forward edge of the hosel, which is connected to the shaft.

2. The golf metal wood club as claimed in claim 1, wherein the club face has a loft and larger the loft is, the smaller the backward shift is within a loft range of 1<loft<=70.

3. A method of making a golf metal wood club having a shaft and a head provided with a club face, the method comprising the steps of:
creating a database based on lofts of all backward shifted club faces of iron clubs;
dividing the database into loft ranges according to loft difference;
finding backward shifted mean in each of the loft ranges;
creating a backward shift prediction table based on the mean of the loft ranges; and
determining backward shifted value of a wood club to be made according to the prediction table.

4. The method as claimed in claim 3, wherein the loft difference between loft ranges has at least 25% overlapping.

5. The method as claimed in claim 3, wherein loft difference in each of the loft ranges is no more than 4 degrees.

6. The method as claimed in claim 4, wherein loft difference in each of the loft ranges is no more than 4 degrees.

7. The method as claimed in claim 3 further comprising a step of providing modification room after the backward shifted mean finding step.

8. The method as claimed in claim 4 further comprising a step of providing modification room after the backward shifted mean finding step.

9. The method as claimed in claim 5 further comprising a step of providing modification room after the backward shifted mean finding step.

10. The method as claimed in claim 6 further comprising a step of providing modification room after the backward shifted mean finding step.

11. The method as claimed in claim 7, wherein the step of providing modification room is to provide a room for adjustment to the backward shifted mean so found.

12. The method as claimed in claim 7, wherein STDEVP is adopted for the modification room providing step.

13. The method as claimed in claim 7, wherein in the mean finding step, element number (>1 and <4) is used to find midpoint between the element.

14. The method as claimed in claim 6, wherein loft difference in each of the loft ranges is 0, 1, 2, 3 or 4.

15. The method as claimed in claim 10, wherein loft difference in each of the loft ranges is 0, 1, 2, 3 or 4.

16. The method as claimed in claim 11, wherein loft difference in each of the loft ranges is 0, 1, 2, 3 or 4.

17. The method as claimed in claim 12, wherein loft difference in each of the loft ranges is 0, 1, 2, 3 or 4.

18. The method as claimed in claim 13, wherein loft difference in each of the loft ranges is 0, 1, 2, 3 or 4.
